(19) United States
(12) Patent Application Publication
(10) Pub. No.: US 2025/0113452 A1
(43) Pub. Date: Apr. 3, 2025

(54) COMPOSITE MOLDED COMPONENT

(71) Applicant: Sumitomo Wiring Systems, Ltd., Yokkaichi-Shi, Mie (JP)

(72) Inventors: Yukitoshi TERASAKA, Suzuka-Shi (JP); Toshinari KOBAYASHI, Suzuka-Shi (JP); Megumi YAMAO, Suzuka-shi, Mie (JP); Hiroyuki KOYANO, Suzuka-shi, Mie (JP)

(73) Assignee: Sumitomo Wiring Systems, Ltd., Yokkaichi-Shi, Mie (JP)

(21) Appl. No.: 18/833,168

(22) PCT Filed: Jan. 11, 2023
(86) PCT No.: PCT/JP2023/000373

§ 371 Date: Jul. 25, 2024

(30) Foreign Application Priority Data
Jan. 28, 2022 (JP) 2022-011927

(51) Int. Cl. H05K 5/02; G01P 1/02

(52) U.S. Cl. CPC H05K 5/0247; H05K 5/0217; G01P 1/026

(57) ABSTRACT

This composite molded component includes an internal component, a primary molded portion that covers the internal component, and a secondary molded portion that covers the primary molded portion. The primary molded portion of the composite molded component includes a through hole portion that penetrates to the internal component, and an annular rib portion that protrudes toward the secondary molded portion so as to surround a positioning portion of the primary molded portion. At least a portion of the through hole portion and at least a portion of the annular rib portion are overlapped with each other in the lengthwise direction of the secondary molded portion.

### CROSS-REFERENCE TO RELATED APPLICATIONS

This application is the U.S. national stage of PCT/JP2023/000373 filed on Jan. 11, 2023, which claims priority of Japanese Patent Application No. JP 2022-011927 filed on Jan. 28, 2022, the contents of which are incorporated herein.

### TECHNICAL FIELD

The present disclosure relates to a composite molded component.

### BACKGROUND

Vehicles such as automobiles include a wheel speed sensor that measures the rotational speed of a wheel. A device such as that described in JP 2017-096828A is known as an example of such a wheel speed sensor. The wheel speed sensor described in JP 2017-096828A includes a detection unit in which a detection element portion is provided, a holder portion that holds the detection unit, and a resin molded portion that serves as a cover for covering the detection unit. The detection element portion is embedded in one end side of the resin molded portion, and a wire harness extends from the other end side of the resin molded portion.

In order to improve the fit between the holder portion and the resin molded portion, a rib is sometimes provided on a portion of the contact portion of the holder portion that comes into contact with the resin molded portion. It is therefore necessary to ensure space for the rib portion.

Also, there has been strong demand in recent years for automobiles and the like to be made smaller and lighter in weight. There is also growing demand for reduction in the size of composite molded components in which an electrical component is covered with multiple resin portions, such as a wheel speed sensor.

In view of this, an object of the present disclosure is to provide a composite molded component that can be made smaller.

### SUMMARY

A composite molded component according to an aspect of the present disclosure includes: an internal component; a primary molded portion covering the internal component; and a secondary molded portion covering the primary molded portion, wherein the primary molded portion includes at least one through hole portion penetrating to the internal component, and at least one annular rib portion protruding toward the secondary molded portion so as to surround a positioning portion of the primary molded portion, and at least a portion of the at least one through hole portion and at least a portion of the at least one annular rib portion are overlapped with each other in a lengthwise direction of the secondary molded portion.

### Advantageous Effects

According to the present disclosure, it is possible to provide a composite molded component that can be made smaller by shortening a secondary molded portion in the lengthwise direction.

### BRIEF DESCRIPTION OF DRAWINGS

FIG. 1 is a perspective view of a composite molded component.

FIG. 2 is a perspective view of the composite molded component.

FIG. 3 is a side view of the composite molded component.

FIG. 4 is a plan view of the composite molded component.

FIG. 5 is a cross-sectional view taken along a line V-V in FIG. 4.

FIG. 6 is a cross-sectional view of a primary molded portion together with a mold, taken along a line VI-VI in FIG. 4.

FIG. 7 is a cross-sectional view of the primary molded portion together with the mold, taken along a line VII-VII in FIG. 4.

FIG. 8 is a cross-sectional view of the primary molded portion together with the mold, taken along a line VIII-VIII in FIG. 4.

FIG. 9 is a plan view of a primary molded portion according to a second embodiment.

FIG. 10 is a cross-sectional view of a primary molded portion according to a third embodiment together with a mold, taken at a position corresponding to the VI-VI cross section in FIG. 4.

### DETAILED DESCRIPTION OF PREFERRED EMBODIMENTS

First, embodiments of the present disclosure will be listed and described.

A composite molded component according to an aspect of the present disclosure is as follows.

A composite molded component includes: an internal component; a primary molded portion covering the internal component; and a secondary molded portion covering the primary molded portion, wherein the primary molded portion includes at least one through hole portion penetrating to the internal component, and at least one annular rib portion protruding toward the secondary molded portion so as to surround a positioning portion of the primary molded portion, and at least a portion of the at least one through hole portion and at least a portion of the at least one annular rib portion are overlapped with each other in a lengthwise direction of the secondary molded portion.

According to the present disclosure, at least a portion of the through hole portion and at least a portion of the annular rib portion are overlapped with each other in the lengthwise direction of the secondary molded portion, and thus the secondary molded portion can be shortened in the lengthwise direction. Accordingly, the composite molded component can be made smaller overall.

An aspect is possible in which the at least one through hole portion includes a first through hole portion and a second through hole portion, the at least one annular rib portion includes a first annular rib portion, and the first through hole portion and the second through hole portion are located on opposite sides of the first annular rib portion in a width direction perpendicular to the lengthwise direction. According to the present disclosure, the secondary molded portion can be shortened in the lengthwise direction, and the mold can stably support the internal component during primary molding.

An aspect is possible in which the at least one annular rib portion further includes a second annular rib portion and a third annular rib portion, and the second annular rib portion and the third annular rib portion are side by side along the width direction at positions different from the first annular rib portion in the lengthwise direction. According to the present disclosure, the secondary molded portion can be shortened in the lengthwise direction, and the mold can stably support the internal component during primary molding.

An aspect is possible in which the first through hole portion and the second through hole portion are formed at respective outward ends of the internal component in the width direction, and penetrate in a direction according to which respective side surfaces of the internal component in the width direction are exposed. According to the present disclosure, the mold can also restrict the internal component in the width direction during primary molding.

An aspect is possible in which the internal component includes two parallel lead wires, the at least one through hole portion includes a third through hole portion, and the third through hole portion penetrates at a position exposing a portion of each of the two lead wires. According to the present disclosure, the mold can stably support the lead wires during primary molding.

Specific examples of a composite molded component of the present disclosure will be described below with reference to the drawings. Note that the present disclosure is not limited to these examples, but rather is indicated by the scope of the claims, and is intended to include all changes within the meaning and scope equivalent to the scope of the claims.

In the drawings, parts of configurations may be exaggerated or simplified for convenience of description. Furthermore, the dimensional ratios of parts may differ among the drawings. Also, in this specification, the terms “parallel” and “orthogonal” do not only mean strictly parallel and strictly orthogonal, but also include approximately parallel and approximately orthogonal to the extent that operations and effects of the present embodiment are achieved.

### First Embodiment

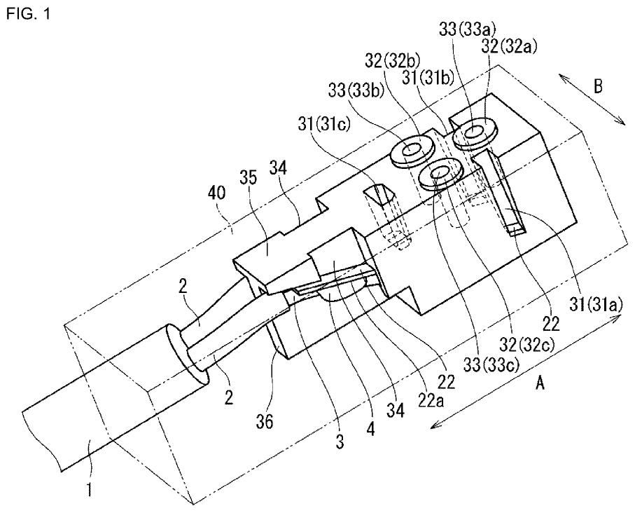

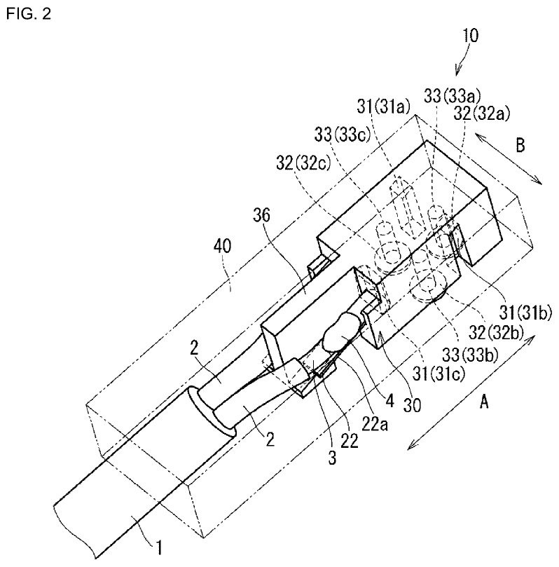

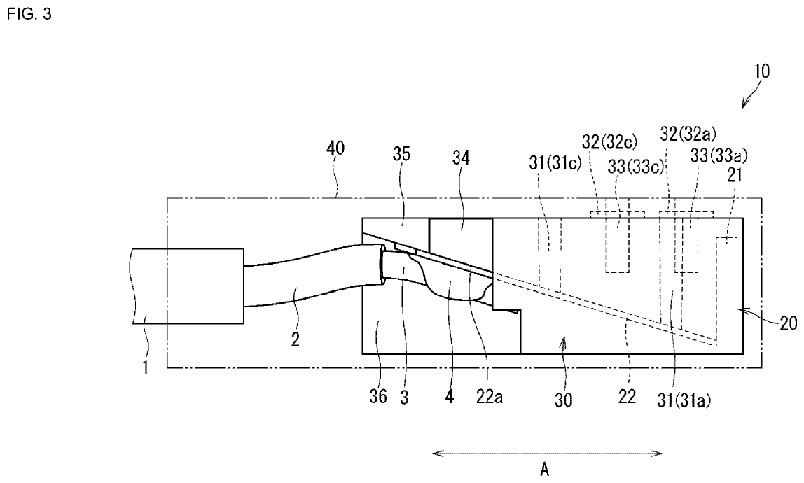

A composite molded component 10 according to a first embodiment will be described below. FIG. 1 is a perspective view of the composite molded component 10. FIG. 2 is a perspective view of the composite molded component 10 from a different direction than FIG. 1. FIG. 3 is a side view of the composite molded component 10. Note that in all of these drawings, a secondary molded portion 40 is shown by virtual lines.

### Composite Molded Component 10

The composite molded component 10 includes an internal component 20, a primary molded portion 30, and a secondary molded portion 40. The composite molded component 10 is used to measure the rotational speed of a vehicle tire, for example.

### Internal Component 20

The internal component 20 includes an element body portion 21 and lead wires 22. In the present embodiment, the internal component 20 includes two parallel lead wires 22. Each of the lead wires 22 has a leading end portion that is exposed from the primary molded portion 30. A portion of the leading end portion of the lead wire 22 exposed from the primary molded portion 30 is a soldering portion 22a. The soldering portion 22a is the portion to be soldered to a conductor end portion 3. The conductor end portion 3, which is the leading end portion of a coated electric wire 1, is fixed to the soldering portion 22a by solder 4. The conductor end portion 3 is the portion where an insulating coating 2 covering the conductor has been stripped off to expose the conductor. After the lead wires 22 and the conductor end portions 3 are secured together, the internal component 20 and the primary molded portion 30 are molded using a secondary molded portion 40. In the present embodiment, the element body portion 21 is shaped as a flattened rectangular parallelepiped. A plurality of (here, two) lead wires 22 extend from one peripheral side portion of the element body portion 21. The lead wires 22 extend to one side in the thickness direction of the element body portion 21. The lead wires 22 extend obliquely relative to the upper surface of the element body portion 21. The lead wires 22 may be orthogonal to or parallel with the upper surface of the element body portion 21.

The element body portion 21 detects a magnetic physical quantity or an amount of change thereof, for example. The value detected by the element body portion 21 is transmitted to a control unit (not shown) and used to measure the rotational speed of a wheel, for example. The element body portion 21 has a rectangular shape, for example. In the following description, the lengthwise direction of the secondary molded portion 40 refers to the longest direction among three directions parallel with respective sides of the rectangular parallelepiped-shaped secondary molded portion 40, envisioning the state where the internal component 20 is covered by the primary molded portion 30 and the secondary molded portion 40. In other words, the element body portion 21 is held by the primary molded portion 30, and the element body portion 21 and the primary molded portion 30 are covered by the secondary molded portion 40. The element body portion 21 is embedded in a portion near one end of the secondary molded portion 40 in the lengthwise direction, and the lead wires 22 extends toward the other end of the secondary molded portion 40 in the lengthwise direction. In other words, the secondary molded portion 40 is elongated in one direction in order for the element body portion 21 to be housed in one end portion and the lead wires 22 to be housed in the other end portion. The lengthwise direction of the secondary molded portion 40 may be considered to be the direction that connects the portion that houses the element body portion 21 and the portion that houses the lead wires 22. In the figures, the lengthwise direction of the secondary molded portion 40 is indicated by an arrow A.

### Primary Molded Portion 30

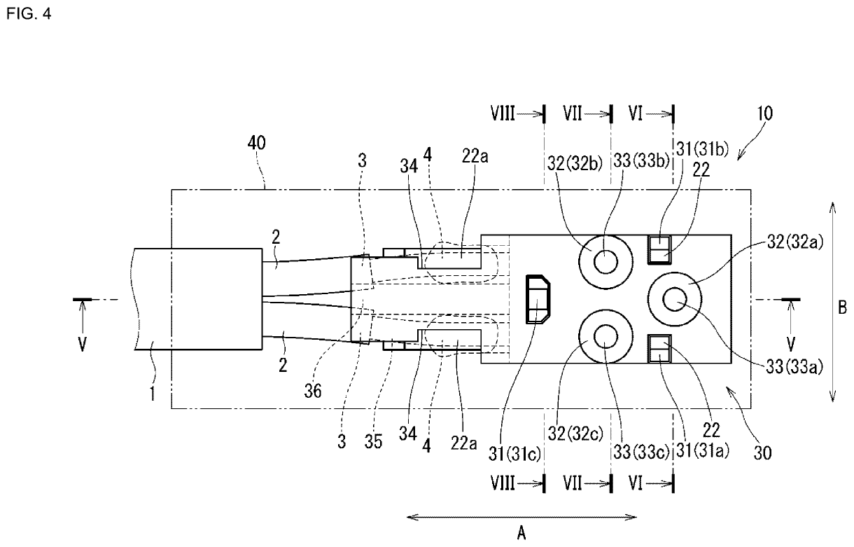

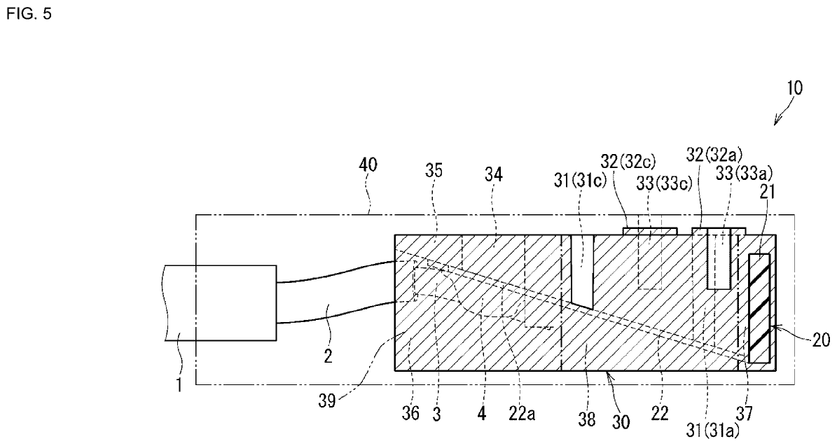

FIG. 4 is a plan view of the composite molded component 10. Also, FIG. 5 is a cross-sectional view taken along a line V-V in FIG. 4. The primary molded portion 30 is a resin portion that covers the internal component 20. The primary molded portion 30 is a portion molded using the same resin material as the internal component 20 as an insert. The primary molded portion 30 includes through hole portions 31 that penetrate to the internal component 20, and annular rib portions 32.

More specifically, the primary molded portion 30 includes a body housing portion 37, a lead wire base end housing portion 38, and a lead wire leading end holding portion 39. The body housing portion 37 covers the element body portion 21. The lead wire base end housing portion 38 is continuous with the side of the body housing portion 37 from which the lead wires 22 extend. The body housing portion 37 and the lead wire base end housing portion 38 are shaped as a rectangular parallelepiped. The base end portion of the lead wire 22 is embedded in the lead wire base end housing portion 38.

The lead wire leading end holding portion 39 extends from the lead wire base end housing portion 38 on the side opposite to the body housing portion 37. The lead wire leading end holding portion 39 includes lead wire placement portions 35 that correspond to the lead wires 22, and a partition portion 36. The lead wire placement portions 35 extend along one main surface of the lead wires 22 extending from the lead wire base end housing portion 38. The partition portion 36 extends between the lead wire placement portions 35 so as to separate the lead wires 22 extending from the lead wire base end housing portion 38. The two lead wires 22 are separated by the partition portion 36, thus preventing the lead wires 22 from coming into contact with each other.

When the primary molded portion 30 is molded using the internal component 20 as an insert, the through hole portions 31 are marks formed by the insertion of positioning portions of the mold. The through hole portions 31 penetrate until they reach the upper surface of the internal component 20, and portions of the upper surface of the internal component 20 are exposed in the through hole portions 31. In the present embodiment, the through hole portions 31 are formed in the lead wire base end housing portion 38. Although there are no limitations on the number of through hole portions 31, in the present embodiment, a first through hole portion 31a, a second through hole portion 31b, and a third through hole portion 31c are provided.

The following describes the annular rib portions 32. When molding the secondary molded portion 40 using the primary molded portion 30 as an insert, heated and melted resin for molding the secondary molded portion 40 is injected into the mold apparatus. The heated and melted resin rapidly cools and solidifies upon coming into contact with the surface of the primary molded portion 30. The heated and melted resin that comes into contact with the leading end portions of the annular rib portions 32 does not cool as rapidly as the resin that comes into contact with other portions of the surface of the primary molded portion 30. Therefore, it is expected that the heated and melted resin for forming the secondary molded portion 40 will melt together with the leading end portions of the annular rib portions 32. This results in more complete water stoppage along the annular rib portions 32 at the boundary between the primary molded portion 30 and the secondary molded portion 40. Such annular rib portions 32 are sometimes called melt ribs. It is preferable that the primary molded portion 30 and the secondary molded portion 40 are formed using the same material so that the annular rib portions 32 and the secondary molded portions 40 can easily melt together.

The annular rib portions 32 protrude toward the secondary molded portion 40 so as to surround positioning portions 33 of the primary molded portion 30. When the secondary molded portion is molded using the internal component 20 and the primary molded portion 30 as inserts, the positioning portions 33 are recessions into which positioning portions of the mold are fitted. Although there are no limitations on the number of positioning portions 33, in the present embodiment, the positioning portions 33 include a first positioning portion 33a, a second positioning portion 33b, and a third positioning portion 33c. The annular rib portions 32 include a first annular rib portion 32a that surrounds the first positioning portion 33a, a second annular rib portion 32b that surrounds the second positioning portion 33b, and a third annular rib portion 32c that surrounds the third positioning portion 33c. As shown in FIG. 5, the second annular rib portion 32b and the third annular rib portion 32c are positioned side by side along the width direction of the internal component 20 (parallel direction of the lead wires 22: direction of arrow B) at positions different from the first annular rib portion 32a in the lengthwise direction (arrow A direction) of the secondary molded portion 40. In the present embodiment, the first through hole portion 31a is located closer to the element body portion 21 than the second annular rib portion 32b and the third annular rib portion 32c are.

The first positioning portion 33a is located at the center of the internal component 20 in the width direction (arrow B direction), for example. The second positioning portion 33b and the third positioning portion 33c are located on opposite sides of the center of the internal component 20 in the width direction (arrow B direction). Also, the second positioning portion 33b and the third positioning portion 33c are equidistant from the center of the internal component 20 in the width direction (arrow B direction). Due to the first positioning portion 33a, the second positioning portion 33b, and the third positioning portion 33c being arranged in this manner, the positioning portions 33 are positioned symmetrically across a center line of the internal component 20 in the width direction (arrow B direction). This reduces bias, in the width direction (arrow B direction) of the internal component 20, in the support force by which the primary molded portion 30 is supported by the mold during molding of the secondary molded portion 40. In the present embodiment, the annular rib portions 32 are formed so as to surround the corresponding positioning portions 33, and thus the annular rib portions 32 are also positioned symmetrically about the center line of the internal component 20 in the width direction (arrow B direction).

As shown in FIG. 5, at least a portion of each of the through hole portions 31 and at least a portion of the corresponding annular rib portion 32 are overlapped with each other in the lengthwise direction of the secondary molded portion 40. In the present embodiment, the first through hole portion 31a and the second through hole portion 31b are located on opposite sides of the first annular rib portion 32a in the width direction (arrow B direction), which is perpendicular to the lengthwise direction (arrow A direction) of the secondary molded portion 40. Also, “at least a portion of the through hole portion 31 and at least a portion of the annular rib portion 32 are overlapped with each other in the lengthwise direction of the secondary molded portion” does not mean that the through hole portion 31 and the annular rib portion 32 are overlapped with each other in a plan view. This means that at least a portion of the arrangement region of the through hole portion 31 in the coordinate system along the lengthwise direction (arrow A direction) of the secondary molded portion 40 is overlapped with at least a portion of the arrangement region of the annular rib portion 32. By adopting such an arrangement, the composite molded component 10 can be shortened in the lengthwise direction of the secondary molded portion 40 (the direction of the arrow A). This allows the composite molded component 10 to be made smaller overall.

In the present embodiment, the first through hole portion 31a and the second through hole portion 31b are positioned on opposite sides of the center of the internal component 20 in the width direction (arrow B direction). The first through hole portion 31a and the second through hole portion 31b are equidistant from the center of the internal component 20 in the width direction (arrow B direction). Due to the positions of the first through hole portion 31a and the second through hole portion 31b, it is possible to reduce bias in the supporting force by which the internal component 20 is supported by the mold during molding of the primary molded portion 30.

Also, the third through hole portion 31c is located at a position different from the first through hole portion 31a and the second through hole portion 31b in the lengthwise direction (arrow A direction) of the secondary molded portion 40. In the present embodiment, the third through hole portion 31c is located closer to the leading end portions of the lead wires 22 than the first through hole portion 31a and the second through hole portion 31b are. The third through hole portion 31c is located at the center of the internal component 20 in the width direction (arrow B direction), for example. Due to the first through hole portion 31a, the second through hole portion 31b, and the third through hole portion 31c being arranged in this manner, the through hole portions 31 are positioned symmetrically across the center line of the internal component 20 in the width direction (arrow B direction). This reduces bias, in the width direction (arrow B direction) of the internal component 20, in the support force by which the internal component 20 is supported by the mold during molding of the primary molded portion 30.

Also, as shown in FIGS. 1 and 4, the first through hole portion 31a penetrates at a position where a portion of one of the lead wires 22 is exposed through the primary molded portion 30. Similarly, the second through hole portion 31b penetrates at a position where a portion of the other lead wire 22 is exposed through the primary molded portion 30. Due to the arrangement of the first through hole portion 31a and the second through hole portion 31b, the lead wires 22 are stably supported by the positioning portions of the mold during molding of the primary molded portion 30.

As shown in FIGS. 1 and 4, the third through hole portion 31c penetrates at a position where portions of the two lead wires 22 are exposed through the primary molded portion 30. More specifically, the third through hole portion 31c is a hole wider than the distance between the two lead wires 22. Inward-facing portions of the two lead wires 22 are exposed at the bottom of the third through hole portion 31c. Due to the position of the third through hole portion 31c, the lead wires 22 are stably supported by a positioning pin of the mold during molding of the primary molded portion 30.

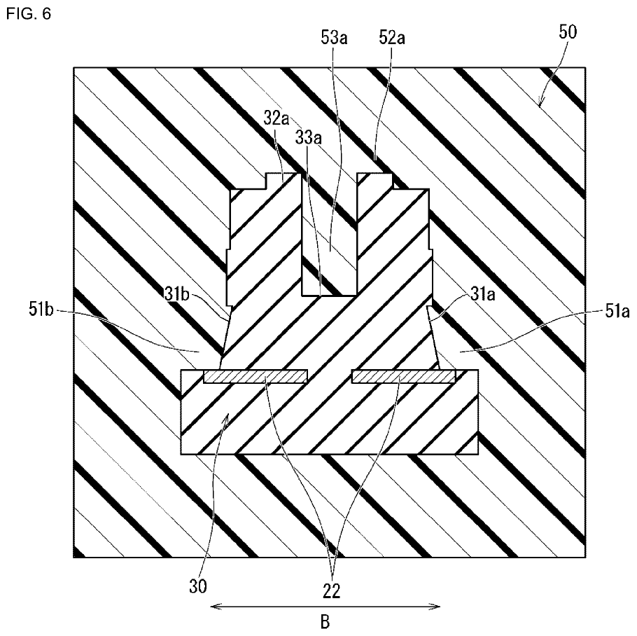

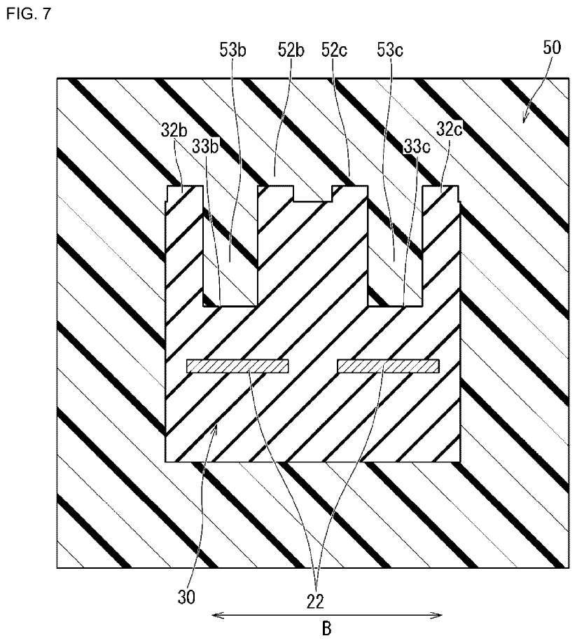

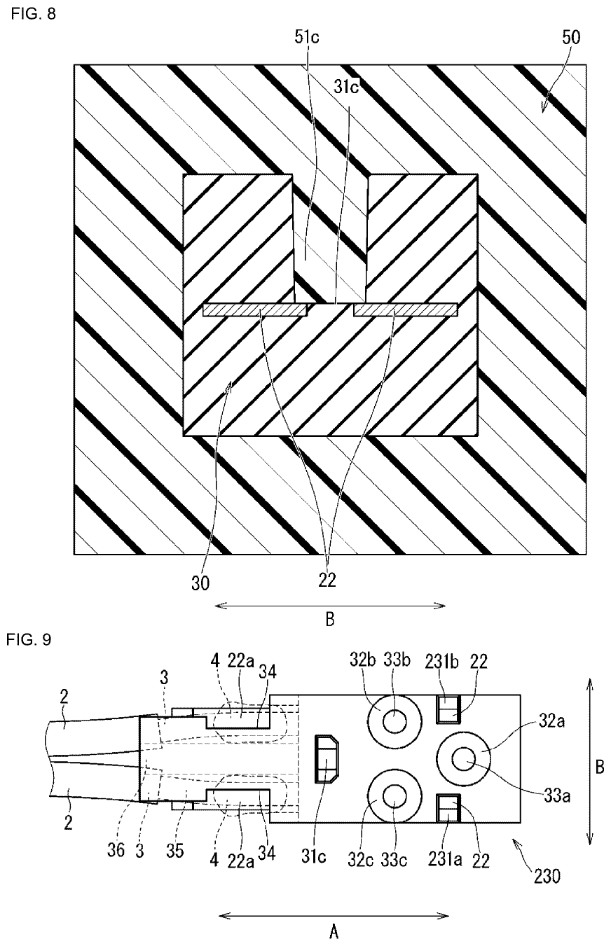

FIG. 6 is a cross-sectional view taken along a line VI-VI in FIG. 4, and shows the primary molded portion 30 together with the mold 50. FIG. 7 is a cross-sectional view of the primary molded portion 30 together with the mold 50, taken along a line VII-VII in FIG. 4. FIG. 8 is a cross-sectional view of the primary molded portion 30 together with the mold 50, taken along a line VIII-VIII in FIG. 4. Note that V-V is a straight line passing through the widthwise center of the internal component 20. Also, in FIGS. 6 to 8, a cross section of the primary molded portion 30 during molding is shown, and the secondary molded portion 40 is not shown.

As shown in FIG. 6, a mold 50 used when molding the primary molded portion 30 includes a positioning portion 51a that forms the first through hole portion 31a, and a positioning portion 51b that forms the second through hole portion 31b. In the present embodiment, the positioning portion 51a and the positioning portion 51b support and fix the lead wires 22. Furthermore, the mold 50 includes a protruding portion 53a that forms the first positioning portion 33a, and a recessed portion 52a that forms the first annular rib portion 32a. In this way, the first through hole portion 31a, the second through hole portion 31b, the first positioning portion 33a, and the first annular rib portion 32a are included in the same cross section taken perpendicular to the lengthwise direction of the secondary molded portion 40 (arrow A direction in FIG. 4), and thus the composite molded component 10 can be shortened in the lengthwise direction of the secondary molded portion 40 (arrow A direction in FIG. 4). Note that the positioning portions 51a and 51b and the protruding portion 53a may be portions formed by protrusions of the mold surface itself, or may be pins added to the mold surface.

As shown in FIG. 7, the mold 50 includes a protruding portion 53b that forms the second positioning portion 33b, and a recessed portion 52b that forms the second annular rib portion 32b. Also, as shown in FIG. 8, the mold 50 includes a positioning portion 51c that forms the third through hole portion 31c. The positioning portion 51c supports and fixes both of the two lead wires 22. Note that the protruding portion 53b and the positioning portion 51c may be portions formed by protrusions of the mold surface itself, or may be pins added to the mold surface.

According to the composite molded component 10 configured as described above, at least a portion of the through hole portion 31 and at least a portion of the annular rib portion 32 are overlapped with each other in the lengthwise direction of the secondary molded portion 40. Therefore, the secondary molded portion 40 can be shortened in the lengthwise direction. Accordingly, the composite molded component 10 can be made smaller overall.

Also, among the through hole portions 31, the first through hole portion 31a and the second through hole portion 31b are located on opposite sides of the first annular rib portion 32a in the width direction (arrow B direction) perpendicular to the lengthwise direction of the secondary molded portion 40. Accordingly, the composite molded component 10 can be shortened in the lengthwise direction of the secondary molded portion 40, and the mold 50 can stably support the internal component 20 during primary molding.

Also, the third through hole portion 31c is formed at a position exposing a portion of each of the two lead wires 22. Accordingly, the mold 50 can stably support the lead wires 22 during primary molding.

### Second Embodiment

FIG. 9 is a plan view of a primary molded portion 230 according to a second embodiment. A first through hole portion 231a and a second through hole portion 231b in the primary molded portion 230 are not open outward in the width direction of the primary molded portion 230 (arrow B direction). In the present embodiment, similarly to the third through hole portion 31c, a first through hole portion 231a and a second through hole portion 231b are formed inside the primary molded portion 230 in a plan view.

### Third Embodiment

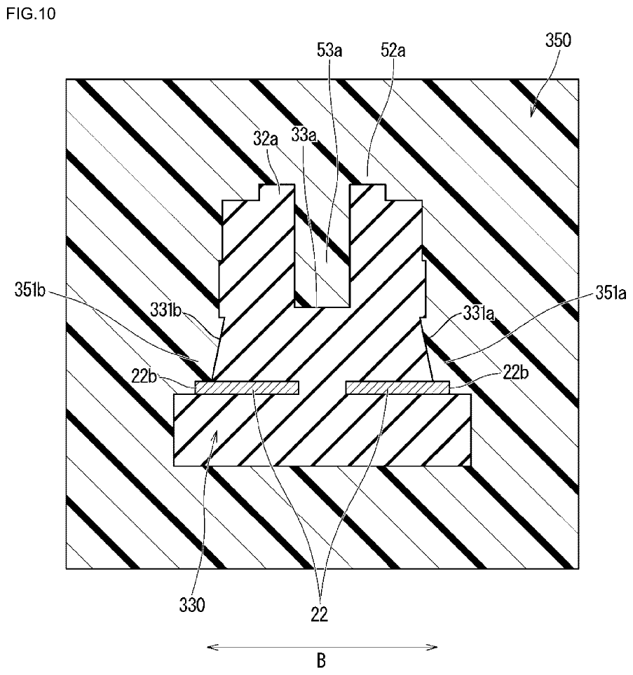

FIG. 10 is a cross-sectional view of a primary molded portion 330 according to a third embodiment together with a mold 350, taken at a position corresponding to the VI-VI cross section in FIG. 4.

As shown in FIG. 10, a first through hole portion 331a and a second through hole portion 331b are formed at respective outward ends of the internal component 20 in the width direction (arrow B direction), and penetrate in a direction according to which respective side surfaces of the internal component 20 in the width direction (arrow B direction) are exposed. In the present embodiment, the first through hole portion 331a and the second through hole portion 331b are formed by a positioning portion 351a and a positioning portion 351b of the mold 350. During primary molding, side surfaces 22b of the lead wires 22 are arranged so as to abut against the positioning portions 351a and 351b of the mold 350. As a result, the side surfaces 22b of the lead wires 22 of the internal component 20 are exposed from the primary molded portion 330. Due to this arrangement of the first through hole portion 331a and the second through hole portion 331b, primary molding is performed in a state where the mold 350 (positioning portion 351a and positioning portion 351b) abuts against the side surfaces 22b of the lead wires 22. Therefore, when the primary molded portion 30 is molded, the width direction (arrow B direction) of the internal component 20 can also be restricted.

### Other Matter

Although three through hole portions 31 (231) are formed in the above embodiments, the number of through hole portions 31 (231) is not limited to three. The scope of the present disclosure encompasses one or more through hole portions 31 (231). Similarly, although three positioning portions 33 (or annular rib portions 32) are formed, there is no limitation to three positioning portions 33 (or annular rib portions 32). The scope of the present disclosure encompasses one or more positioning portions 33 (or annular rib portions 32).

Also, although all of the positioning portions 33 are each surrounded by an annular rib portions 32 in the above-described embodiments, the present disclosure is not limited to this. An annular rib portion 32 does not need to be located at a position surrounding a positioning portion 33. Moreover, a portion of the positioning portions 33 may be surrounded by an annular rib portion 32.

Also, although the through hole portions 31 (231) are positioned symmetrically across the center of the internal component 20 in the width direction (arrow B direction) in the above-described embodiments, the present disclosure is not limited to this. Furthermore, although the positioning portions 33 (or the annular rib portions 32) are also positioned symmetrically across the center of the internal component 20 in the width direction (arrow B direction), the present disclosure is not limited to this. The present disclosure also encompasses any configuration in which at least a portion of a through hole portion 31 (231) and at least a portion of an annular rib portion 32 are overlapped with each other in the lengthwise direction of the secondary molded portion 40.

The configurations described in the first to third embodiments may be combined as appropriate as long as no contradiction arises.

1. A composite molded component comprising:
an internal component;
a primary molded portion covering the internal component; and
a secondary molded portion covering the primary molded portion,
wherein the primary molded portion includes at least one through hole portion penetrating to the internal component, and at least one annular rib portion protruding toward the secondary molded portion so as to surround a positioning portion of the primary molded portion,
at least a portion of the at least one through hole portion and at least a portion of the at least one annular rib portion are overlapped with each other in a lengthwise direction of the secondary molded portion,
the at least one through hole portion includes a first through hole portion and a second through hole portion,
the at least one annular rib portion includes a first annular rib portion,
the first through hole portion and the second through hole portion are located on opposite sides of the first annular rib portion in a width direction perpendicular to the lengthwise direction, and
the first through hole portion and the second through hole portion are formed at respective outward ends of the internal component in the width direction, and penetrate in a direction according to which respective side surfaces of the internal component in the width direction are exposed.

2. (canceled)

3. The composite molded component according to claim 1, wherein the at least one annular rib portion further includes a second annular rib portion and a third annular rib portion, and
the second annular rib portion and the third annular rib portion are side by side along the width direction at positions different from the first annular rib portion in the lengthwise direction.

4. (canceled)

5. The composite molded component according to claim 1, wherein the internal component includes two parallel lead wires,
the at least one through hole portion includes a third through hole portion, and
the third through hole portion penetrates at a position exposing a portion of each of the two lead wires.

6. The composite molded component according to claim 3, wherein the internal component includes two parallel lead wires,
the at least one through hole portion includes a third through hole portion, and
the third through hole portion penetrates at a position exposing a portion of each of the two lead wires.
